(19) United States
(12) Patent Application Publication
(10) Pub. No.: US 2026/0349055 A1
(43) Pub. Date: Nov. 5, 2026

(54) SENSOR SYSTEM FOR DETECTING A MAGNETIC FIELD OR A MAGNETIC FIELD-DEPENDENT MEASURED VARIABLE WITH A MAGNETIC FIELD GENERATION DEVICE HAVING AT LEAST THREE INDIVIDUAL PERMANENT MAGNETS

(71) Applicant: Robert Bosch GmbH, Stuttgart (DE)

(72) Inventors: Sergey Nechayev, Rutesheim (DE); Florian Mauch, Talheim (DE); Julian Kassel, Pforzheim (DE)

(21) Appl. No.: 19/653,928

(22) Filed: Apr. 21, 2026

(30) Foreign Application Priority Data
Apr. 30, 2025 (DE) 10 2025 116 712.5

(51) Int. Cl. G01R 33/26; G01R 33/00; G01R 33/038

(52) U.S. Cl. CPC G01R 33/26; G01R 33/0082; G01R 33/038

(57) ABSTRACT

A sensor system for detecting a magnetic field parameter of an external magnetic field. The sensor system includes an NV diamond, a microwave source, a microwave structure that is arranged and configured to shape an electromagnetic field generated by the microwave source so that a microwave field is generated in the NV diamond, an excitation light source to direct an excitation light beam onto the NV diamond so that, along a beam axis of the excitation light beam, an optical field is formed within the NV diamond, a detector to detect an optical signal emitted by the NV diamond as a result of irradiation with the excitation light beam and a magnetic field generation device to generate a directed internal, static magnetic field within the NV diamond. The magnetic field generation device includes at least three individual permanent magnets that are arranged in exactly one plane.

### CROSS REFERENCE

The present application claims the benefit under 35 U.S.C. § 119 of Germany Patent Application No. DE 10 2025 116 712.5 filed on Apr. 30, 2025, which is expressly incorporated herein by reference in its entirety.

### FIELD

The present disclosure relates to a sensor system for detecting a magnetic field or a magnetic field-dependent measured variable.

### BACKGROUND INFORMATION

So-called NV magnetic field sensors are used to detect a magnetic field. These sensors comprise a diamond with a crystal lattice that has defects in the form of NV centers. In an NV center, a nitrogen atom occupies the lattice site of a carbon atom, wherein a defect is located in direct proximity to the nitrogen atom, again on the lattice site of a carbon atom. When such a crystal lattice is irradiated with excitation radiation having a wavelength between 490 nm and 575 nm, an electronic transition from a ground state ³A₂ to an excited state ³E is induced. The NV center relaxes from the excited state ³E back to the ground state ³A₂ by emitting fluorescent radiation in a wavelength range between 600 nm and 850 nm. The ground state ³A₂ has three magnetic substates where mₛ=0, mₛ=±1. The states where mₛ=0 and mₛ=±1 differ by an energy difference of 2.87 GHz (zero field splitting). The excited state ³E also has three magnetic substates where mₛ=0, mₛ=±1. If the NV center in the ground state ³A₂ is then exposed to microwave radiation with a frequency of 2.87 GHz, the NV center oscillates between the mₛ=0, ³A₂ ground state and the mₛ=±1, ³A₂ ground state. When irradiated with the excitation radiation, the NV center is now partially shifted from the mₛ=±1, ³A₂ ground state to the excited mₛ=±1, ³E state. From there, it relaxes predominantly non-radiatively and without preserving spin back into the mₛ=0, ³A₂ ground state. At the same time, the excited state mₛ=0, ³E also relaxes with emission of fluorescence radiation into the mₛ=0, ³A₂ ground state. If the amplitude of the fluorescence radiation is measured according to the frequency of the microwave radiation during irradiation with the excitation radiation, a sudden drop in the amplitude of the fluorescence radiation (a so-called dip) occurs at a frequency of 2.87 GHz. The drop in the amplitude of the fluorescence radiation can be explained in that – upon irradiation with microwave radiation having a frequency of 2.87 GHz – the transition between the mₛ=0, ³ A₂ ground state and the mₛ=±1, ³A₂ ground state is induced, which is excited without preserving spin by the excitation radiation, but can relax non-radiatively and without preserving spin into the mₛ=0, ³ A₂ ground state. If microwave radiation of a precisely matching frequency is thus irradiated, the mₛ=0, ³ A₂ ground state is depleted, while the mₛ=±1, ³A₂ ground state is populated.

In an external magnetic field, the mₛ=±1, ³A₂ ground state splits into two states with the spin quantum numbers mₛ=1 and mₛ=-1 (Zeeman effect). If the amplitude of the fluorescence radiation is measured with variation of the frequency of the microwave radiation, two dips are obtained, wherein the frequency spacing between the dips is proportional to the projection of the magnetic field onto the direction of the axis of the NV center. The frequencies at which these dips occur depend on the magnitude of the splitting of the mₛ=±1, ³A₂ ground state and thus on the field strength and direction of the external magnetic field.

For the orientation of the axes of the NV centers, four different possibilities result in the crystal lattice of the diamond. If NV axes in each of these four orientations are present in the crystal lattice of the NV diamond, eight dips are obtained in a measurement of the amplitude of the fluorescence radiation with variation of the frequency of the microwave radiation; i.e., the two resonances corresponding to the states with spin quantum numbers mₛ=1 and mₛ=-1 in each case split into four states. In each case, the projection of the magnetic field onto the respective NV centers is detected. In order to avoid an overlap of the corresponding dips at a small external magnetic field, a static magnetic field, hereinafter referred to as an internal, static magnetic field, is thus necessary. The field strength of the internal, static magnetic field must be sufficiently large that the individual resonances resulting for the respective orientations of the NV axes do not overlap and thus an external magnetic field is measured merely in addition to the internal magnetic field. If the resonances lie very close to one another, it may occur that the respective line widths are greater than the splitting.

Such an NV magnetic field sensor is described, for example, in U.S. Patent Application Publication No. US 2019/0018091 A1. The NV magnetic field sensor has a plurality of permanent magnets which generate an internal, static magnetic field. The permanent magnets are arranged in a Halbach arrangement. The excitation radiation is irradiated onto the NV diamond perpendicularly to the plane of the Halbach arrangement.

The sensitivity of the NV magnetic field sensor depends substantially on the homogeneity of the internal, static magnetic field at the location of the NV diamond. This is in most cases directly dependent on the size of the magnetic field generation device. In principle, therefore, magnetic field generation devices having as large a size as possible are typically used. For many applications, however, a magnetic field sensor that is as compact as possible is advantageous. In order to configure the NV magnetic field sensor to be both as compact as possible and as sensitive as possible, it is therefore necessary to improve the sensitivity of the NV magnetic field sensor in another way.

### SUMMARY

The present disclosure relates to a sensor system for detecting a magnetic field parameter of an external magnetic field, e.g., the magnetic field strength of the external magnetic field. According to an example embodiment, such a sensor system has a diamond having at least one NV center (NV diamond). The sensor system further has a microwave source, an excitation light source and a detector. The microwave source is arranged and configured to generate an electromagnetic field. The sensor system further has a microwave structure that is arranged and configured to shape the electromagnetic field generated by the microwave source so that a microwave field is generated in the NV diamond. The excitation light source can be, e.g., a diode laser. The excitation light source is in particular configured to generate an excitation light beam having a wavelength between 490 nm and 575 nm. The excitation light source is further arranged and configured to direct the excitation light beam onto the NV diamond so that, along a beam axis of the excitation light beam, an optical field is formed within the NV diamond, wherein, as a result of irradiation with the excitation light beam, the NV diamond emits an optical signal, in particular fluorescence radiation in a wavelength range between 600 nm and 850 nm. A beam-shaping optical element (e.g., a lens) and/or at least one beam-guiding optical element (e.g., at least one deflection mirror) can be arranged between the excitation light source and the NV diamond. The detector is configured and arranged to detect the optical signal emitted by the NV diamond as a result of irradiation with the excitation light beam. In particular, the detector can be configured as a photodiode that can detect radiation in a wavelength range of the fluorescence radiation emitted by the NV diamond, in particular between 600 nm and 850 nm.

According to an example embodiment, the sensor system further has a magnetic field generation device that is arranged and configured to generate a directed internal, static magnetic field within the NV diamond.

The magnetic field generation device comprises at least three individual permanent magnets that are arranged at least approximately along a circular line in exactly one plane – also referred to here as the xy-plane – according to the Halbach principle. The orientations of the magnetic dipole moments of the at least three individual magnets correspond to the Halbach principle, i.e., for the orientation of the respective individual permanent magnets i: m ᵢ = A (cos2φ, sin2φ, 0), wherein the static internal magnetic field points in the direction (A,0,0). The sign of the constant A defines the polarity. This also applies if no individual permanent magnet is located at the position φᵢ = 0. The beam axis of the excitation light beam extends parallel to the exactly one plane in which the individual permanent magnets are arranged. Such a sensor system has a particularly high sensitivity and is particularly compact at the same time.

In one example embodiment of the present disclosure, between 3 and 64, in particular between 4 and 16, individual permanent magnets are arranged along the circular line in the at least one plane. Such a number of individual permanent magnets can be handled particularly easily, wherein, at the same time, the internal, static magnetic field is highly homogeneous.

The internal, static magnetic field generated by the magnetic field generation device has an increased homogeneity within the NV diamond along a first preferred axis. The first preferred axis extends parallel to the exactly one plane and is oriented perpendicular to the direction of the internal, static magnetic field. The internal, static magnetic field has the increased homogeneity in a volume around the preferred axis. The volume has, in particular, an elongated shape along the first preferred axis. The first preferred axis extends, in particular, at a distance of h/2 from the exactly one plane (xy-plane). h is the height of the individual permanent magnets measured perpendicular to the xy-plane. If individual permanent magnets of different height are present, the first preferred axis extends along an averaged height.

In one example embodiment of the present disclosure, within the NV diamond the beam axis of the excitation light beam is oriented along the first preferred axis. In this way, the spatial region in which the internal, static magnetic field has the increased homogeneity is optimally utilized, so that a particularly compact and at the same time highly sensitive sensor system is made possible.

In one example embodiment of the present disclosure, the magnetic field generation device comprises four individual permanent magnets arranged in one plane and arranged as a Halbach arrangement. These are arranged at least approximately along the circular line and with an angular offset of at least approximately 90° relative to one another. The magnetic dipole moments of the individual permanent magnets are oriented at least approximately parallel or antiparallel to one another and at least approximately perpendicular to the internal, static magnetic field generated by the magnetic field generation device. In principle, the following applies for the orientation of the respective individual permanent magnets i: m ᵢ = A (cos2φ, sin2φ, 0), wherein the static internal magnetic field points in the direction (A,0,0). The sign of the constant A defines the polarity. For example, in each case individual permanent magnets are located at angles of φ = 45°, φ = 135°, φ = 225° and φ = 315°. In the case that the sign of the constant A is positive, the internal, static magnetic field points in the positive x-direction. The magnetic dipole moments of the individual permanent magnets arranged at the positions φ = 45° and φ = 225° likewise point in the positive y-direction. The magnetic dipole moments of the individual permanent magnets arranged at the positions φ = 135° and φ = 315° point in the negative y-direction. The magnetic dipole moments of all four individual permanent magnets are oriented perpendicular to the direction of the internal, static magnetic field. Such an arrangement of the individual permanent magnets makes a particularly homogeneous internal, static magnetic field possible.

In one example embodiment of the present disclosure, the magnetic field generation device has eight individual permanent magnets. The eight individual permanent magnets are arranged at least approximately on the circular line, wherein the angular offset between adjacent individual permanent magnets is 45°. For example, individual permanent magnets are located at angles of φ = 45°, φ = 90°, φ = 135°, φ = 180°, φ = 225°, φ = 270°, φ = 315° and φ = 360°. The magnetic dipole moments of adjacent individual magnets are in each case oriented perpendicular to one another. Such a magnetic field generation device generates, in particular along the first preferred axis, a particularly homogeneous static internal magnetic field.

In one example embodiment of the present disclosure, the magnetic field generation device has a temperature gradient, wherein the temperature gradient is oriented transverse, in particular perpendicular, to the first preferred axis. The temperature gradient can be attributed to the fact that some of the components of the sensor system, such as, e.g., the excitation light source, the microwave structure and/or the NV diamond, act as heat sources when the sensor system is in an activated state. A temperature distribution, the exact profile of which results from the arrangement of the heat sources within the sensor system and the respective amounts of heat that these deliver during operation of the sensor system, occurs in the region of the magnetic field generation device.

The NV diamond and the microwave structure are typically arranged centrally within the magnetic field generation device, so that a heat input caused by these two components occurs at least approximately symmetrically with respect to the magnetic field generation device, i.e., the NV diamond and the microwave structure heat all subregions of the magnetic field generation device to at least approximately the same extent (symmetric heat sources). It is assumed that the components of the sensor system surrounding the magnetic field generation device have at least approximately isotropic thermal conductivity.

However, the excitation light source is not arranged centrally in relation to the magnetic field generation device and thus acts as an asymmetric heat source in relation to the magnetic field generation device. The sensor system can have further components that are not arranged centrally within the magnetic field generation device and that likewise act as asymmetric heat sources with respect to the magnetic field generation device. A heat input attributable to the excitation light source or another asymmetric heat source is not carried out uniformly over the magnetic field generation device. A larger amount of heat is delivered to those subregions of the magnetic field generation device that have a small distance from the asymmetric heat source than to those subregions of the magnetic field generation device that are arranged at a greater distance from the asymmetric heat source. From the interaction of the various asymmetric heat sources, a temperature gradient results with respect to the magnetic field generation device – i.e., in the region of the magnetic field generation device.

Those subregions of the magnetic field generation device which are positioned closer to the asymmetric heat source(s), in particular the excitation light source, have a higher temperature than those subregions of the magnetic field generation device which are arranged farther away therefrom. In particular, the temperature of a first subregion of the magnetic field generation device, which has the greatest distance from the asymmetric heat source(s), in particular the excitation light source, is minimal, while the temperature of a second subregion of the magnetic field generation device, which has the smallest distance from the asymmetric heat source(s), in particular the excitation light source, is maximal. Considering exclusively the temperature of the magnetic field generation device, a temperature profile results in which the temperatures increase from the first subregion of the magnetic field generation device, which is farthest from the asymmetric heat source(s), in particular the excitation light source, toward the second subregion of the magnetic field generation device, which is closest to the asymmetric heat source(s), in particular the excitation light source; i.e., the temperature gradient extends in this direction. Due to this temperature gradient, a reduced homogeneity of the internal, static magnetic field results. The reason for this is that the remanence of magnetic materials is typically temperature-dependent. This temperature dependence ranges from 0.001% per °C for temperature-stabilized SmCo magnets up to 0.2% per °C for hard ferrites.

According to one example embodiment of the present disclosure, the temperature gradient is oriented transverse, in particular at least approximately perpendicular, to the first preferred axis. In this way, the influence of the temperature gradient on the internal, static magnetic field is minimized. This increases the homogeneity of the internal, static magnetic field, which in turn increases the sensitivity of the sensor system.

Such an arrangement makes it possible to further increase the homogeneity of the internal, static magnetic field along the first preferred axis. In particular, the internal, static magnetic field has increased homogeneity along a particularly long distance compared to differently constructed magnetic field generation devices.

In one example embodiment of the present disclosure, the static internal magnetic field along the first preferred axis, along which the static internal magnetic field has increased homogeneity, assumes in particular a value between 99.9% and 100.1% of an average vector field.

The increased homogeneity is, in particular, between 10 ppm and 10000 ppm, preferably between 200 ppm and 2000 ppm, wherein ppm stands for "parts per million." For the considered volume, the following applies:

1,000,000 * || B(x,y,z)-<B> || / || <B> || < homogeneity value in ppm,

wherein ||.|| denotes the norm of the particular vector and <B> is the average vector value of the magnetic field in the considered volume.

A sensor system having a magnetic field generation device, which generates an internal, static magnetic field with such increased homogeneity, has a particularly high sensitivity.

In one example embodiment of the present disclosure, the individual permanent magnets are configured as segments of a circular ring. The segments are, in particular, to be understood as segments of a circular ring divided transverse to its circumferential direction, in particular radially. The magnetic dipole moments of the respective individual permanent magnets point in exactly one direction over their entire volume in each case. Individual magnets configured in this way can be positioned particularly precisely, so that – due to a very small positioning error – the magnetic field generation device generates a particularly homogeneous internal, static magnetic field.

In one example embodiment of the present disclosure, non-magnetized regions are arranged between the individual permanent magnets, which are in each case configured as segments of a circular ring. This makes it possible to use comparatively strongly magnetized magnetic materials for the individual permanent magnets and nevertheless achieve a comparatively low target value for the magnitude of the internal, static magnetic field. In this way, it is possible to use strongly magnetized magnetic materials in a compact structure which nevertheless generate – as desired – a small internal, static magnetic field of, e.g., between 1 mT and 2 mT.

In one example embodiment of the present disclosure, the individual permanent magnets configured as segments of the circular ring are in each case arranged directly adjacent to one another, so that overall a closed circular ring is present. This facilitates the positioning of the individual permanent magnets, so that – due to the very small positioning error – the magnetic field generation device generates a particularly homogeneous internal, static magnetic field.

In one example embodiment of the present disclosure, the individual permanent magnets are configured as cuboids, cubes or cylinders, wherein their magnetic dipole moments are oriented along a particular main axis of symmetry, i.e., in the case of configuration as a cylinder along the axis of rotation of the cylinder, and in the case of configuration as a cuboid along the longitudinal axis of the cuboid. Cuboid-shaped, cylindrical or cube-shaped individual permanent magnets are particularly simple and robust to manufacture.

### BRIEF DESCRIPTION OF THE DRAWINGS

FIG. 1 shows an example embodiment of the sensor system according to the present disclosure having a magnetic field generation device, which has four individual permanent magnets arranged in exactly one plane and arranged according to a Halbach arrangement.

FIGS. 2A-2C show various example embodiments of the magnetic field generation device of the sensor system according to the present disclosure with four individual permanent magnets arranged according to a Halbach arrangement in a top view.

FIG. 3 shows a further example embodiment of the magnetic field generation device of the sensor system according to the present disclosure with eight individual permanent magnets arranged in the exactly one plane and according to a Halbach arrangement in a top view.

### DETAILED DESCRIPTION OF EXAMPLE EMBODIMENTS

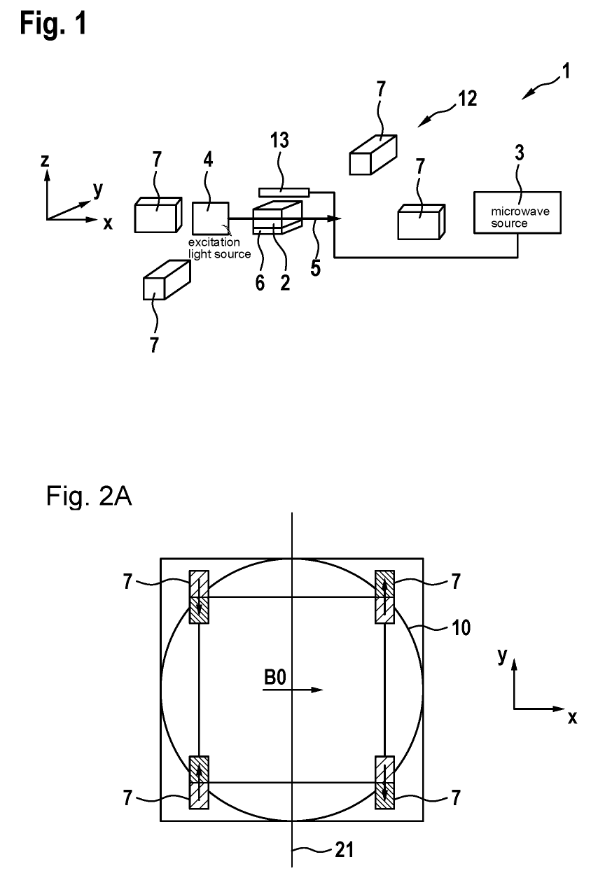

FIG. 1 shows an overview of a sensor system 1 for detecting a magnetic field parameter of an external magnetic field. The sensor system 1 has a diamond crystal with NV defects (NV diamond 2), a microwave source 3, an excitation light source 4, at least one detector 6, at least one reference detector – not shown here – and a magnetic field generation device 12. Optical filters – not shown here – can be arranged at the detector 6 and/or the reference detector, which are in each case configured to block wavelength ranges that are not to be detected or cannot be detected by the detector 6 and/or the reference detector. The detector 6 and/or the reference detector can be configured as photodiodes. The excitation light source 4 is configured to emit an excitation light beam 5. The wavelength of the excitation light beam 5 is, in particular, in a range between 490 nm and 575 nm. The NV diamond 2 and the excitation light source 4 are oriented and arranged relative to one another so that the NV diamond 2 can be irradiated with the excitation light beam 5. The excitation light beam 5 can be guided, e.g., via a, e.g., partially reflective mirror onto the NV diamond 2, wherein the reflected portion of the excitation light beam 5 can be directed onto the NV diamond 2 and the transmitted portion of the excitation light beam 5 can be directed onto the reference detector. Further optical elements, e.g., deflection mirrors, can be provided to guide the excitation light beam 5 onto the NV diamond 2. The microwave source 3 is configured to emit an electromagnetic field that can be guided to a microwave structure 13. The microwave structure 13 is arranged and configured to shape the electromagnetic field so that a microwave field is generated in the NV diamond 2. The detector 6 is configured to detect fluorescence radiation, e.g., in a wavelength range between 600 nm and 850 nm, and is configured, e.g., as a photodiode. The detector 6 can be directly attached to a side surface of the NV diamond 2. Optionally, between the NV diamond 2 and the detector 6, a filter can be arranged which is configured to separate the fluorescence radiation from the excitation light beam. A plurality of detectors, in particular a plurality of photodiodes, can also be provided in order to detect exclusively the fluorescence radiation or to detect simultaneously the fluorescence radiation and the excitation light beam 5. The at least one detector 6 and/or the at least one reference detector can optionally be preceded by filters that filter out predetermined wavelength ranges from the incoming radiation. The magnetic field generation device 12 is configured and arranged to generate a static internal magnetic field B in the NV diamond 2.

Here, the magnetic field generation device 12 comprises four individual permanent magnets 7 that are arranged in one plane according to a Halbach arrangement. The individual permanent magnets 7 are arranged at least approximately along a first circular line 10 – not shown in FIG. 1 – wherein the NV diamond 2 is arranged at the center of the magnetic field generation device 12, i.e., at the center of a circle bounded by the circular line 10. A beam axis of the excitation light beam 5 extends at least within the NV diamond 2 parallel to the exactly one plane in which the individual permanent magnets 7 are arranged. In the embodiment of the present disclosure according to FIG. 1, the individual permanent magnets 7 are arranged in each case with an angular offset of at least approximately 90° relative to one another.

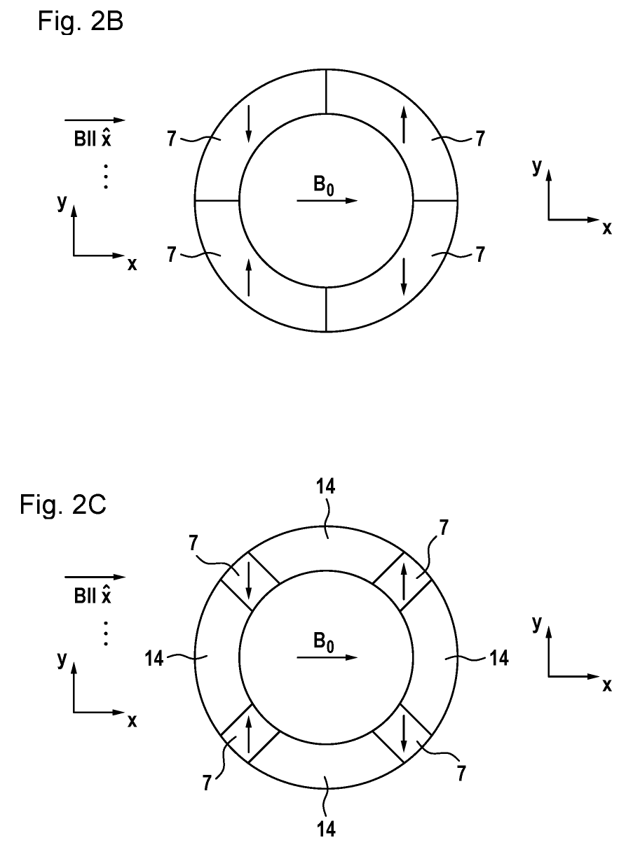

FIG. 2A shows the magnetic field generation device 12 with exactly four individual permanent magnets 7. The magnetic dipole moments of the four individual permanent magnets 7 are oriented in each case parallel or antiparallel to one another and perpendicular to the internal, static magnetic field that they generate and that, in this case, points in the positive x-direction. The individual permanent magnets 7 are arranged at angles of φ = 45°, φ = 135°, φ = 225° and φ = 315°. The magnetic dipole moments of the individual permanent magnets arranged at the positions φ = 45° and φ = 225° point in the positive y-direction. The magnetic dipole moments of the individual permanent magnets arranged at the positions φ = 135° and φ = 315° point in the negative y-direction. The magnetic dipole moments of all four individual permanent magnets are oriented perpendicular to the direction of the internal, static magnetic field (here, the positive x-direction).

The internal, static magnetic field has an increased homogeneity along a first preferred axis 21; i.e., in particular, along the first preferred axis and along a first distance, the field of the internal, static magnetic field deviates by, e.g., at most 0.1% from the average vector field. The first preferred axis extends perpendicular to the direction of the internal, static magnetic field, i.e., in this case in the y-direction. The internal, static magnetic field has increased homogeneity in a volume around the preferred axis 21. It is understood that the volume has an elongated shape along the preferred axis 21, wherein its maximum extent corresponds to the first distance. The first preferred axis 21 extends, in particular, at a distance of h/2 from the exactly one plane (xy-plane). h is the height of the individual permanent magnets measured perpendicular to the xy-plane. If individual permanent magnets of different height are present, the first preferred axis extends along an averaged height. The first preferred axis 21 thus extends through the center of the arrangement, in which the NV diamond 2 (not shown here) is arranged.

The magnetic field generation device 12 shown in FIG. 2B is similar to the magnetic field generation device 12 shown in FIG. 2A; however, the individual permanent magnets 7 are in each case configured in the shape of a segment of a circular ring. The four individual permanent magnets 7 are arranged so that overall a complete ring is present. The magnetic dipole moments of the individual permanent magnets 7 are oriented as in the magnetic field generation device 12 shown in FIG. 2A. The separate individual permanent magnets 7 are in each case completely magnetized, i.e., over the entire segment of the circular ring, along a single direction.

The magnetic field generation device 12 shown in FIG. 2C is similar to the magnetic field generation device 12 shown in FIGS. 2A and 2B. The magnetic dipole moments of the individual permanent magnets 7 are oriented as in the magnetic field generation device 12 shown in FIG. 2A. Like the individual permanent magnets 7 from FIG. 2B, the first individual permanent magnets 7 are in each case configured in the shape of a segment of a circular ring. However, in contrast to the magnetic field generation device from FIG. 2B, between the respective individual permanent magnets 7 non-magnetized regions 14 are present which are each likewise configured in the shape of a segment of the circular ring. An advantage of this arrangement is that a lower field strength is present at the center than in the magnetic field generation device from FIG. 2B (assuming that the first individual permanent magnets 7 from FIGS. 2B and 2C are magnetized equally strongly).

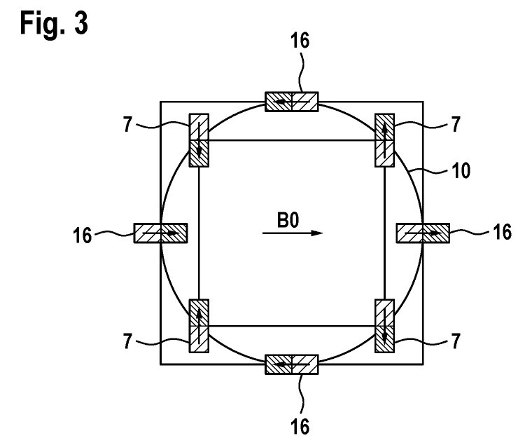

FIG. 3 shows an embodiment of the present disclosure in which the magnetic field generation device 12 comprises eight individual permanent magnets 7, 16. Four individual permanent magnets 7 are arranged along the circular line 10 as in the exemplary embodiments according to FIGS. 2A-2C. Their magnetic dipole moments point perpendicular to the direction of the internal, static magnetic field. Arranged between each of these four individual permanent magnets 7 are further individual permanent magnets 16, the magnetic dipole moments of which are oriented parallel or antiparallel to the direction of the internal, static magnetic field. The internal, static magnetic field generated by the total of eight individual permanent magnets 7, 16 extends in the positive x-direction.

What is claimed is:

1. A sensor system for detecting a magnetic field parameter of an external magnetic field, the sensor system comprising:
an NV diamond;
a microwave source configured to generate an electromagnetic field;
a microwave structure that is arranged and configured to shape the electromagnetic field generated by the microwave source so that a microwave field is generated in the NV diamond;
an excitation light source that is arranged and configured to direct an excitation light beam onto the NV diamond so that, along a beam axis of the excitation light beam, an optical field is formed within the NV diamond;
at least one detector that is arranged and configured to detect an optical signal emitted by the NV diamond as a result of irradiation with the excitation light beam; and
a magnetic field generation device that is arranged and configured to generate a directed internal, static magnetic field within the NV diamond;
wherein the magnetic field generation device has at least three individual permanent magnets that are arranged in exactly one plane and at least approximately along a circular line as a Halbach arrangement, wherein, within the NV diamond, the beam axis of the excitation light beam extends parallel to the exactly one plane.

2. The sensor system according to claim 1, wherein the magnetic field generation device includes between 3 and 64 individual permanent magnets.

3. The sensor system according to claim 1, wherein the NV diamond is arranged at least approximately at a center of a circle bounded by the circular line.

4. The sensor system according to claim 1, wherein the internal, static magnetic field within the NV diamond has an increased homogeneity along a first preferred axis, which extends perpendicular to a direction of the internal, static magnetic field and parallel to the exactly one plane, and wherein, within the NV diamond, the beam axis of the excitation light beam is oriented along the first preferred axis.

5. The sensor system according to claim 1, wherein the individual permanent magnets are configured as segments of a circular ring.

6. The sensor system according to claim 5, wherein non-magnetized regions are arranged between the individual permanent magnets along the circular line.

7. The sensor system according to claim 5, wherein the individual permanent magnets are arranged directly adjacent to one another.

8. The sensor system according to claim 1, wherein the individual permanent magnets are configured as cuboids or cubes or cylinders, wherein magnetic dipole moments of the individual permanent magnets are oriented along a main axis of symmetry.

9. The sensor system according to claim 1, wherein the magnetic field generation device, for generating the internal, static magnetic field, includes eight individual permanent magnets, magnetic dipole moments of the individual permanent magnets are each oriented at least approximately perpendicular or parallel to a direction of the internal, static magnetic field generated by the magnetic field generation device.

10. The sensor system according to claim 4, wherein the magnetic field generation device has a temperature gradient and the temperature gradient is oriented perpendicular to the first preferred axis.
